(19) United States
(12) Patent Application Publication
(10) Pub. No.: US 2002/0124128 A1
(43) Pub. Date: Sep. 5, 2002

(54) Server array hardware architecture and system

(76) Inventor: Ming Qiu, Reno, NV (US)

Correspondence Address: OPPENHEIMER WOLFF & DONNELLY LLP, 2029 CENTURY PARK EAST, 38TH FLOOR, LOS ANGELES, CA, 90067-3024, US

(21) Appl. No.: 10/038,493

(22) Filed: Dec. 31, 2001

Related U.S. Application Data
(60) Provisional application No. 60/259,381, filed on Dec. 29, 2000.

(51) Int. Cl. H05K 7/10; G06F 13/00

(52) U.S. Cl. 710/302

(57) ABSTRACT

A midplane board of a high-density server has mounted to it eight processor cards having modified CPCI form factors, multiple hard drive cards and a KMV switch card, all networked together using redundant network control cards through network connections formed from a CPCI J2 bus. Power is supplied to the processor cards by redundant power supply cards through the CPCI J2 bus as well. The processor cards and power supply cards are mounted to the back side of the midplane board while the multiple hard drive cards, the KMV switch card and expansion cards are mounted to the front side of the midplane board. All cards are hot swappable and configured horizontally on the midplane board. Each processor card controls two expansion cards through the CPCI J1 bus passing through the midplane board. The processor card pinout is the mirror image of that of traditional CPCI front side processor cards.

The present invention claims the benefit of U.S. Provisional Application No. 60/259,381, filed Dec. 29, 2000 which is hereby incorporated by reference in its entirety into the present specification.

### BACKGROUND OF THE INVENTION

1. Field of the Invention

The present invention relates to a computer network architecture, and more particularly to an integrated modular multiple server system utilizing a modified CompactCPI form factor.

2. General Background and State of the Art

In computers, clustering is the use of multiple computers, typically PCs or UNIX workstations, multiple storage devices, and redundant interconnections, to form what appears to users as a single highly available system. Clustering can be used for load balancing as well as for high availability. The traditional server cluster allows unlimited numbers of servers to be scaled up in a single large logical entity to provide higher computing and service capability. In addition to the performance boost, the server cluster can provide redundancy to failover the fault of any single PC server. One of the main ideas of clustering is that, to the outside world, the cluster appears to be a single system.

As mentioned above, a common use of clustering is load balancing. Often clustering is used to load balance traffic on high-traffic Web sites. Load balancing is dividing the amount of work that a computer has to do between two or more computers so that more work gets done in the same amount of time and, in general, all users get served faster. Load balancing can be implemented with hardware, software, or a combination of both. A Web page request is sent to a “manager” server, which then determines which of several identical or very similar Web servers to forward the request to for handling. One approach is to route each request in turn to a different server host address in a domain name system (DNS) table, round-robin fashion. Having a Web farm (as such a configuration is sometimes called) allows traffic to be handled more quickly. Since load balancing requires multiple servers, it is usually combined with failover and backup services. In some approaches, the servers are distributed over different geographic locations.

Another common use for clustering is high availability. In information technology, high availability refers to a system or component that is continuously operational for a desirably long length of time. Availability can be measured relative to “100% operational” or “never failing.” A widely-held but difficult-to-achieve standard of availability for a system or product is known as “five 9s” (99.999 percent) availability.

Since a computer system or a network consists of many parts in which all parts usually need to be present in order for the whole to be operational, much planning for high availability centers around backup and failover processing and data storage and access. For storage, a redundant array of independent disks (RAID) is one approach. A more recent approach is the storage area network (SAN).

Some availability experts emphasize that, for any system to be highly available, the parts of a system should be well-designed and thoroughly tested before they are used. For example, a new application program that has not been thoroughly tested is likely to become a frequent point-of-breakdown in a production system.

Clustering can also be used as a relatively low-cost form of parallel processing for scientific and other applications that lend themselves to parallel operations. An early and well-known example was the Beowulf project in which a number of off-the-shelf PCs were used to form a cluster for scientific applications.

Other uses for clustering include Web page serving and caching, SSL encrypting of Web communication, transcoding of Web page content for smaller displays, streaming audio and video content, file sharing, Web page serving and caching SSL encrypting of Web communication.

Clustering has been available since the 1980s when it was used in DEC's VMS systems. IBM's sysplex is a clustering approach for a mainframe system. Microsoft, Sun Microsystems, and other leading hardware and software companies offer clustering packages that are said to offer scalability as well as availability. As traffic or availability assurance increases, all or some parts of the cluster can be increased in size or number.

However, problems with the traditional clustering of computers include the complex cabling interconnections among the servers and the required space for accommodating large numbers of servers. Moreover, if one server board fails, the whole chassis has to be pulled out for CPU board trouble-shooting.

High-density servers solve some of the problems of traditional server clustering. The configuration of a high-density server can range from a single server to a hundred or more servers within a single rack. To add or remove a server to/from the clustering, one only needs to remove a CPU board from the chassis. High-density servers often use a single set of peripheral devices (CD-R drive, FDD drive, keyboard, video display, and mouse) shared by all the systems within the rack.

One popular type of high-density server is the “blade server”. Blade servers solve the problem of entangled cables through the use of KVM control systems. They often include redundant power supplies and a hot-swappable system board. A blade server is a thin, modular electronic circuit board, containing one, two, or more microprocessors and memory, that is intended for a single, dedicated application (such as serving Web pages) and that can be inserted into a space-saving rack with many similar servers. It is known to include 280 blade server modules positioned vertically in multiple racks or rows of a single floor-standing cabinet. Blade servers, which share a common high-speed bus, are designed to create less heat and thus save energy costs as well as space. Large data centers and Internet service providers (ISPs) that host Web sites are among companies using blade servers.

Like most clustering applications, blade servers can also be managed to include load balancing and failover capabilities. A blade server usually comes with an operating system and the application program to which it is dedicated already on the board.

The existing high-density servers have had several problems including high cost, lack of compatibility and lack of versatility. Existing high-density servers use proprietary hardware and software sold at relatively low volumes and high profit margins making the systems very costly. The existing high-density servers are often incompatible with third-party expansion cards and other third-party components resulting in their limited versatility.

Compact peripheral component interconnect (CPCI or CompactCPI), on the other hand, provides a standard for computer backplane architecture and peripheral integration allowing use of standard third-party expansion cards, components and software. CPCI is electrically a superset of desktop peripheral component interconnect (PCI) with a different physical form factor. CPCI utilizes the Eurocard form factor popularized by the VME bus. Peripherals or expansion cards occupy slots on a backplane, derive their power from this, and utilize a processor card such as a mother card, server card, motherboard or system slot board having CPUs, also occupying a slot on the backplane, to drive the applications associated with them.

CPCI provides a standard high-speed PCI local bus interface between the expansion cards, processor card and backplane. A bus is a transmission path on which signals are dropped off or picked up at every device attached to the line. Only devices addressed by the signals pay attention to them; the others discard the signals. The PCI standard is a bus standard developed for PCs by INTEL that can transfer data between the CPU and card peripherals at much faster rates than are possible via the ISA bus (e.g., about 132 Mbps as opposed to 5 Mbps).

FIG. 1 shows a typical CPCI backplane 11 of the prior art viewed from the front of the system chassis. A CPCI system is composed of one or more CPCI bus segments. Each segment is composed of up to eight CPCI card locations 13 with 20.32 mm (0.8 inch) card center-to-center spacing. Each CPCI segment consists of one system slot 15, and up to seven peripheral slots or expansion slots 17.

The system slot card is positioned in the system slot 15 and provides arbitration, clock distribution, and reset functions for all cards on the segment. The system slot is responsible for performing system initialization by managing each local card's IDSEL signal. Physically, the system slot may be located at any position in the backplane. The peripheral slots 17 may contain simple boards or cards, intelligent slaves, or PCI bus masters.

Eight CPCI front side male (pin) connectors 19 are shown attached to the backplane 11 at each of the card locations 13 of FIG. 1. FIG. 2 shows a female (socket) connector 21 for attaching CPCI cards to the card locations 13 via the front side pin connectors 19. Each connector consists of two halves—the lower half (110 pins) is called J1 and the upper half (also 110 pins) is called J2. Connector keying is implemented on the J1 connector to physically prevent incorrect installation of the cards and includes a wider key 23 for fitting into a wider mating slot or groove 27 and a narrower key 25 for fitting into a narrower mating slot or groove 29. FIG. 1 only illustrates the mating slots for one of the connectors but it is understood that the other connectors also include mating slots.

In certain telecommunications applications, cards are connected on the back side of the CPCI backplane (in which case the backplane is a midplane). This permits manufacturers to design cards that serve only to terminate external input and output interfaces. All processor activity can then be concentrated on the front side of the card, allowing all cabling associated with a particular card to be plugged into an electrical interface on the back side of the card. Because it is divided into two sections, the front or processor section, when it must be replaced, can be removed using the physical ejector levers provided without disturbing the cabling secured to the rear portion. Back-side pin connectors having a form factor the mirror image of the front-side pin connectors 19 are attached to the back side of the midplane. The mating slots of the back-side connectors are also the mirror images of the front-side connector mating slots 27, 29. Thus, cards having front-side female connectors 21 will not fit into the midplane board's male back-side pin connectors because the keys of the front-side female connectors will not fit into the mating slots of the midplane board male back-side connectors. Instead, cards to be inserted into the back side pin connectors utilize a back-side female connector having a form factor the mirror image of the front side female connectors including reversed connector keys which will fit into the mating slots of the back-side connectors.

The cards for inserting into the card locations 13 utilize the CPCI form factor illustrated in FIG. 3. The form factor defined for CPCI cards is based upon the Eurocard industry standard. Both 3U (100 mm wide by 160 mm long) and 6U (233.35 mm wide by 160 mm long) card sizes are defined. The 3U (100 mm width) form factor is illustrated in FIG. 3.

The 3U form factor is the minimum for CPCI as is accommodates the full 64 Bit CPCI bus. The 6U extensions are defined for cards where the extra card area or connection space is needed.

Each J1/J2 connector has 220 pins for all power, ground, and all 32 and 64 bit PCI signals. J1 is used for the 32-bit PCI signals. The signals of J2 are user defined and can be used for 64-bit PCI transfers or for rear-panel I/O. Plug in cards that only perform 32 bit transfers can use a single 110 pin connector (J1). 32 bit cards and 64 bit cards can be intermixed and plugged into a single 64 bit backplane. FIG. 4 shows the pinout diagram for the J1 connectors of the front side of the midplane. A pinout is a description of the purpose of each pin in a multi-pin hardware connection interface. The pin assignments of FIG. 4 correspond to the J1 pins of the connectors 19 shown in FIG. 1.

6U cards can have J3 through J5 connectors for application use. Applications can include rear-panel I/O, bused signals (e.g. H.110), or custom use.

However, CPCI has not been optimized for implementing a high-density server. It would be desirable to provide a high density server which takes advantage of the compatibility and versatility of CPCI architecture.

### INVENTION SUMMARY

A general object of the present invention is to provide a reliable, versatile and economical high density server. An embodiment of the present invention is achieved by mounting to a midplane board, eight processor cards, multiple hard drive cards and a KMV switch card, all networked together using redundant network control cards through network connections formed from a CPCI J2 bus. Power is supplied to the processor cards by redundant power supply cards through the CPCI J2 bus as well. The processor cards and power supply cards are mounted to the back side of the midplane board while the multiple hard drive cards, the KMV switch card and expansion cards are mounted to the front side of the midplane board. All cards are configured horizontally and stacked in columns on the midplane board to efficiently utilize the area of the front and back sides of the midplane board. Each processor card controls two expansion cards through the CPCI J1 bus passing through the midplane board providing increased efficiency over the traditional CPCI arrangement in which one controller card controls seven expansion cards. The processor card pinout is the mirror image of the pinout of traditional CPCI front side processor cards and of the pinout for the expansion cards, allowing the unique back side positioning of the processor cards. The processor cards utilize a modified CPCI card form factor by having longer lengths allowing for placement of more components and cheaper components on the cards while reducing overheating problems. The processor cards, hard drive cards and network control cards are redundant so that the high density server continues to operate even if one or more of the cards fail. Additionally, the high density server utilizes the hot swap capability of CPCI to allow replacement of the cards while the high density server continues to operate. The system is easily upgradeable and expandable by adding or replacing any of the cards plugged into the front side or back side of the midplane.

A more general embodiment of the invention comprises a midplane board having opposing front and back sides; midplane board front-side connector connected to the front side of the midplane board; an expansion card having an expansion-card connector connected to the front-side connector; a midplane board back-side connector connected to the back side of the midplane board; electrically conductive leads passing through the midplane board and electrically connecting the expansion card to the back-side connector; and a processor card having a processor-card connector connected to the back-side connector such that the pinout assignments of the processor card are the mirror images of the pinout assignments of the expansion card.

Another general embodiment of the invention comprises a midplane board having opposing front and back sides; multiple processor cards physically and electrically connected to the midplane board; multiple network control cards physically and electrically connected to the midplane board; and multiple power supply cards physically and electrically connected to the midplane board.

A further general embodiment of the invention comprises a midplane board having opposing front and back sides; multiple expansion cards physically and electrically connected to the front side of the midplane board through a CompactPCI pin connector; multiple processor cards physically and electrically connected to the back side of the midplane board through a reversed CompactPCI pin connector; wherein the processor cards have a length of greater than 160 millimeters.

### BRIEF DESCRIPTION OF THE DRAWINGS

FIG. 1 shows a typical CPCI backplane of the prior art viewed from the front of the system chassis.

FIG. 2 shows a prior art female (socket) connector for attaching CPCI cards to front side of the midplane.

FIG. 3 shows a prior art form factor for CPCI expansion cards.

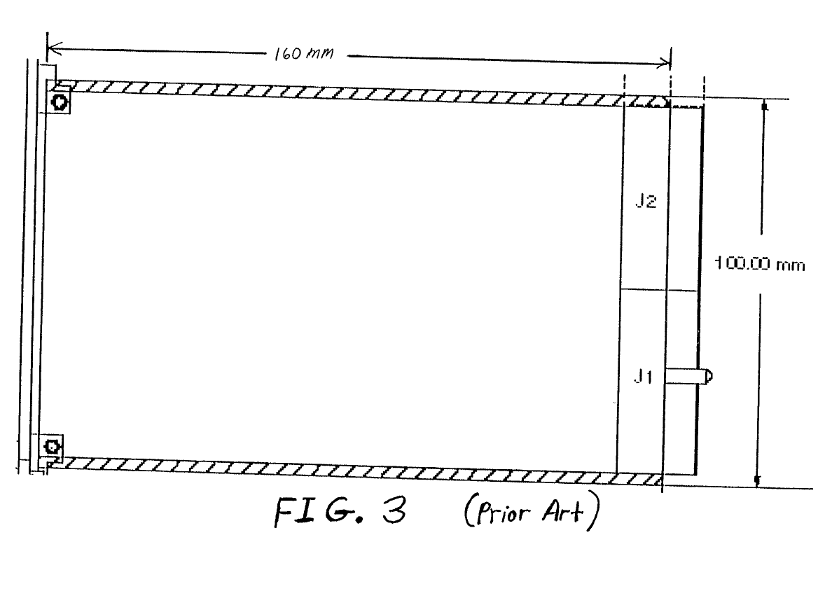

FIG. 4 shows the pinout diagram for the male J1 connectors of the front side of the midplane board.

FIG. 5 shows the physical arrangement of the server array of the present invention.

FIG. 6 shows a housing for enclosing the server array.

FIG. 7 illustrates the front side of a 3U version of the midplane board.

FIG. 8 illustrates pinouts for the J1 connectors on the back side of the midplane board.

FIG. 9 shows the functional infrastructure of an embodiment of the server array.

FIG. 10 illustrates a server array for e-server applications.

FIG. 11 illustrates a server array for terminal server, web server, network routing or security applications.

FIG. 12 shows a server array including a horizontally oriented 6U width processor card.

FIG. 13 illustrates a server array to serve as a small business server.

FIG. 14 illustrates a server array for utility server applications.

FIG. 15 illustrates a server array also for utility server applications.

FIG. 16 illustrates a server array used for enterprise server applications.

FIG. 17 illustrates another utility server.

FIG. 18 illustrates a server array serving as an enterprise server.

FIG. 19 illustrates a server array serving as a power server.

FIG. 20 illustrates another layout of a server array.

FIG. 21 shows the relationships between the pinouts of FIGS. 4 and 8.

FIG. 22 is a schematic diagram illustrating a network control card a female connector.

FIG. 23 is a schematic diagram illustrating a processor card having a back-side female connector which is the mirror image of the female connector of FIG. 2.

FIG. 24 shows the user defined J2 pinout assignments for the CPUs of the processor cards.

### DETAILED DESCRIPTION OF THE PREFERRED EMBODIMENTS

While the specification describes particular embodiments of the present invention, those of ordinary skill can devise variations of the present invention without departing from the inventive concept.

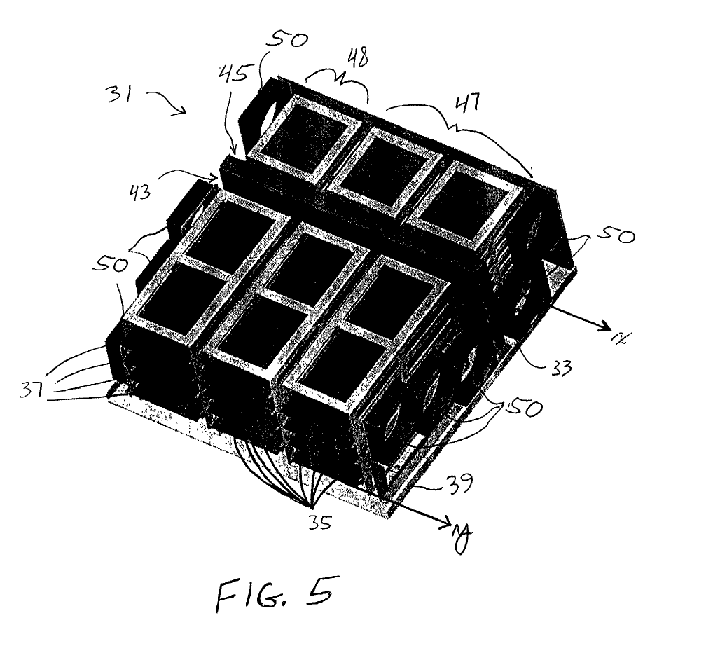

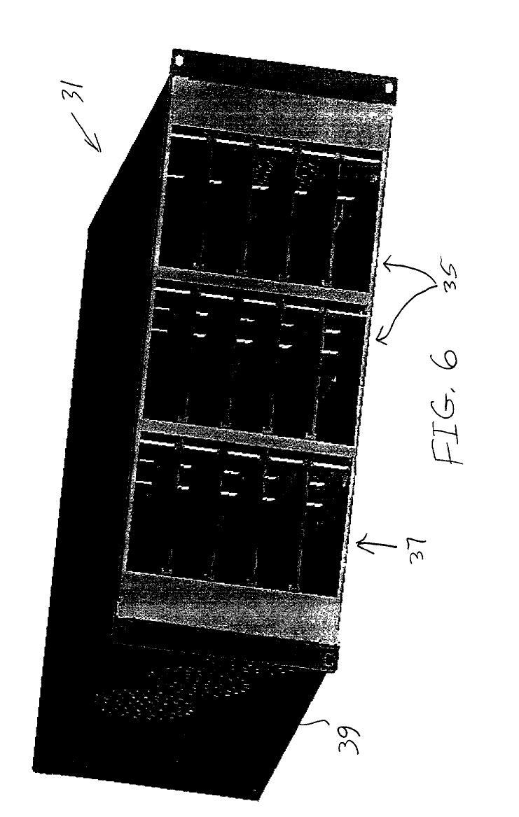

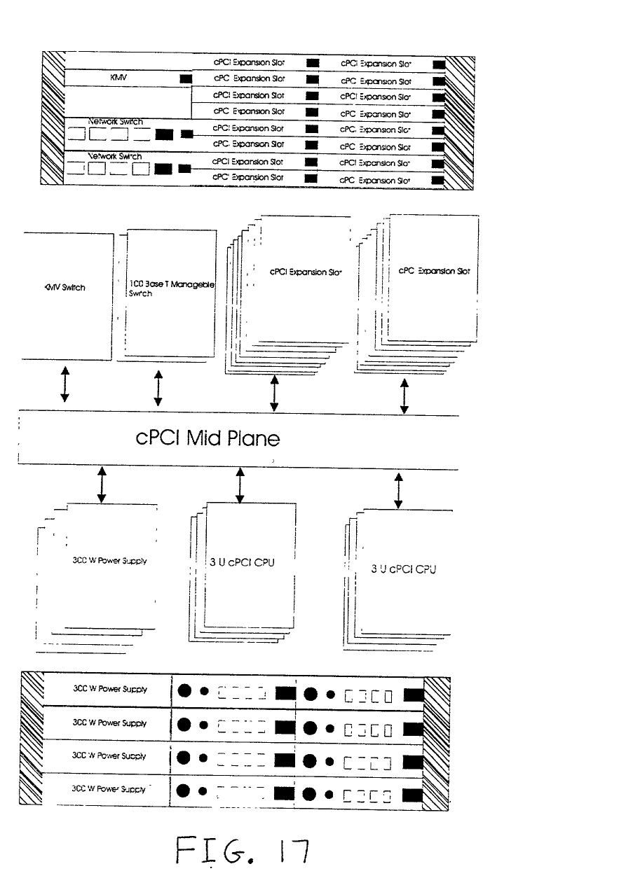

FIG. 5 illustrates an exemplary physical arrangement of a server array 31. This arrangement corresponds to the schematic diagram of FIG. 17. A midplane 33 is shown vertically positioned and having a longer edge defining an x-axis. Two columns each having four horizontally oriented processor cards 35 such as a mother cards, server cards, motherboards or system slot boards having CPUs are attached to the back side 43 of the midplane 33. Also attached to the back side 43 of the midplane 33 is a column of four horizontally oriented redundant power supply cards 37. At the front side 45 of the midplane 33 are two horizontally oriented columns of expansion cards 47 and a column of cards 48 including at least one network control card. The cards 35, 37, 47, 48 have edges defining a y-axis as shown in FIG. 5. When the cards are horizontally oriented the x-axis is parallel to the y-axis. Several fans 50 pass air across the cards 35, 37, 47, 48 to provide cooling. The server array 31 is supported by chassis 39. FIG. 6 is a more complete view of the chassis 39 showing the cards 35, 37 enclosed therein. The server array 31 is designed to fit into standard 19″ wide standard telecom racks having heights ranging from 1U to 8U depending on model (1U=1.75″).

Alternatively the cards 35, 37, 47, 48 can be vertically oriented so that each of the cards is oriented with the y-axis perpendicular to the x-axis. The vertical orientation is advantageous in that it provides better cooling since the heat can rise along the vertical spaces between the cards. The horizontal orientation is advantageous in that it provides more space for inserting more cards into the midplane board 33. Also, different numbers and combinations and types of cards can be used in the present invention as described below.

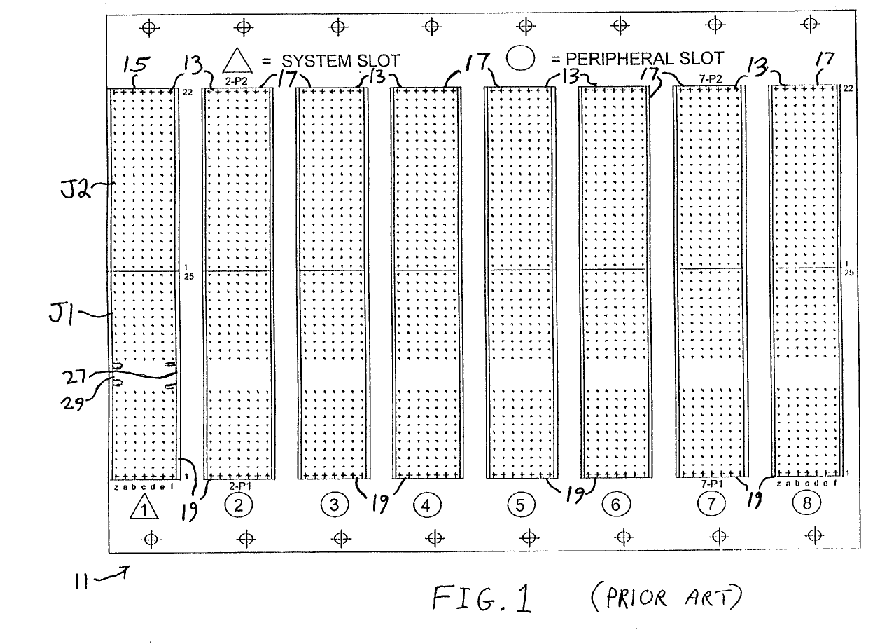

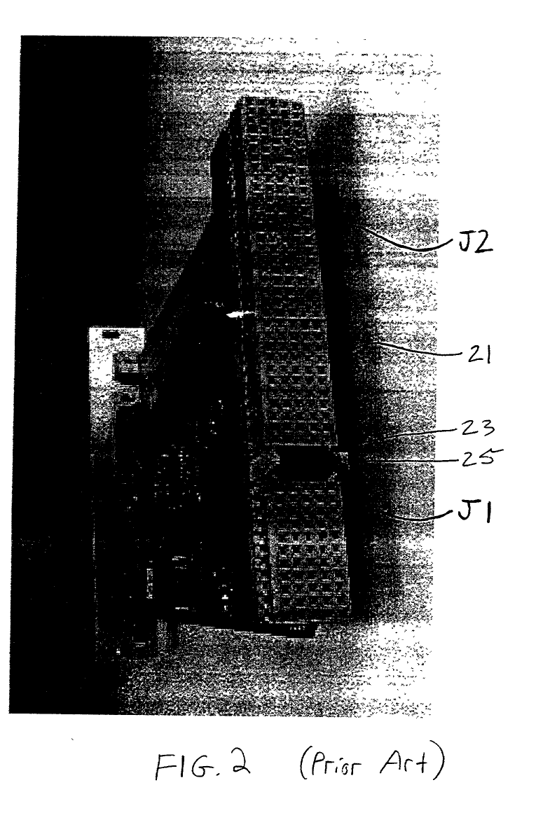

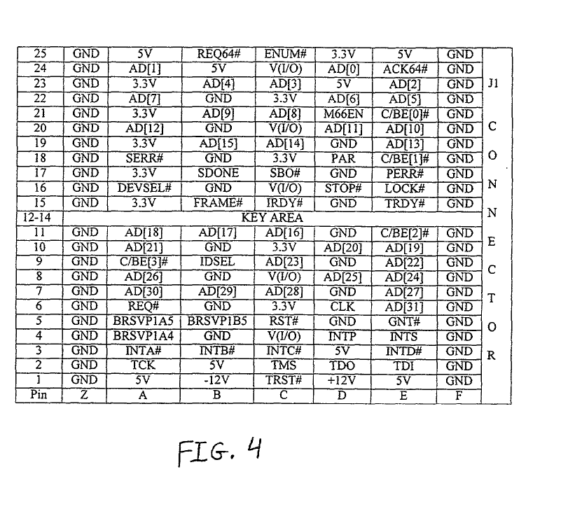

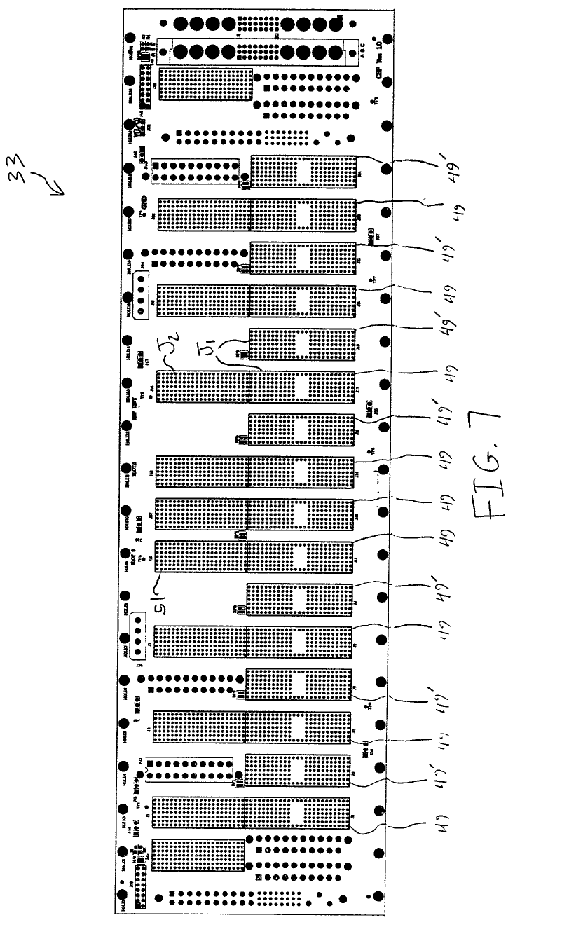

FIG. 7 illustrates the front side of a 3U (approximately 5 inches high and 16.9 inches long) version of the midplane 33 of the present invention. This particular embodiment has multiple CPCI card locations 49, 49′ oriented for vertical card configuration, however, the following description also applies to the embodiment of the invention in which card locations are oriented for horizontal card configuration. The board is an 8 layer PCB with circuit traces formed on several of the layers. Each of the board locations 49, 49′ has multiple conductively plated through holes 51 passing through to the back side of the midplane 33 for transmitting signals through the midplane 33. The locations 49 are disposed for attachment of the CPCI front side male (pin) connectors 19 of FIG. 1. The pinouts for the J1 segments of the board locations 49, 49′ are shown in FIG. 4. CPCI cards having the female (socket) connector 21 of FIG. 2 are attached to the board locations 49 via the front side pin connectors 19. The locations 49′ are disposed for attachment of connectors having the J1 pins but not the J2 pins.

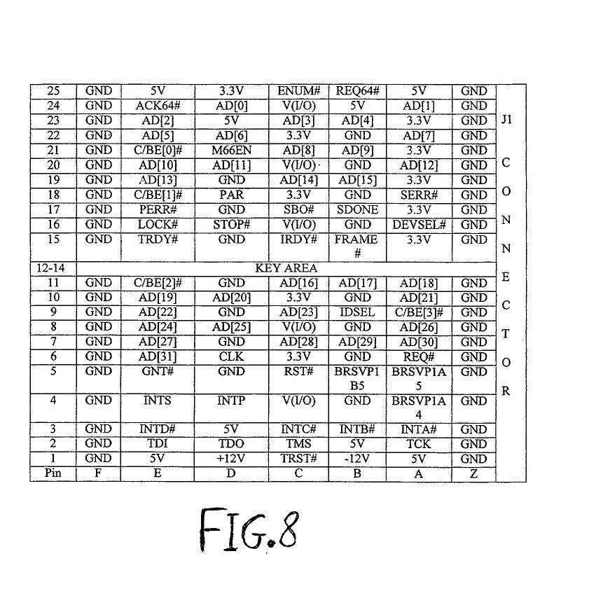

The plated though holes on the back side of the midplane 33 are obviously the mirror image of the plated through holes 51 on the front side of the midplane 33. Back-side pin connectors having a form factor the mirror image of the front-side pin connectors 19 are attached to the back side of the midplane. The pinouts for the J1 segments on the back side of the midplane 33 are illustrated in FIG. 8. Boards having female connectors which are the mirror image of the female connector 21 of FIG. 2 are attached to the board locations 49 via the back-side pin connectors.

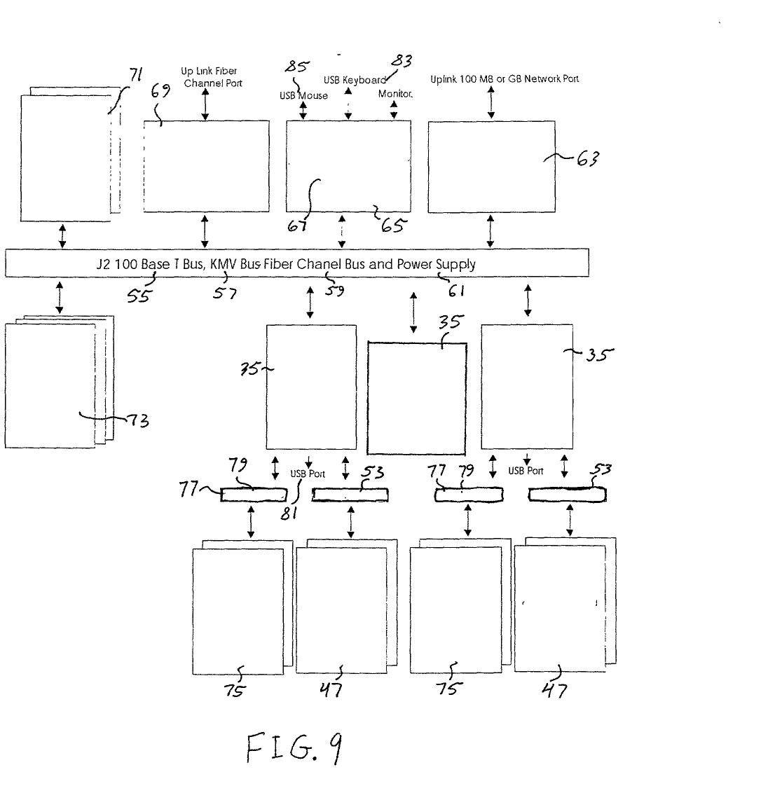

FIG. 9 shows the functional infrastructure of an embodiment of the server array of the present invention. A J1 CPCI system bus 53, J2 100 base T bus 55, KMV bus 57, fiber channel bus 59 and power supply paths 61 are all supported on the midplane board 33 of FIG. 7.

Mounted on the midplane board 33 are multiple processor cards 35 (each capable of supporting several CPUs), multiple hard drive cards 71 and a KMV (Keyboard, Mouse and Video Switch) switch card 65, all networked together using redundant network control cards (100 base T manageable network switch cards or a network hub card) 63 through the bus connections 55, 57, 59 formed from the CPCI J2 bus 55. Thus an Ethernet, or other network system, is formed through the midplane board 33 using the J2 bus to connect each of the processor cards 35 to each other and to the network switch cards.

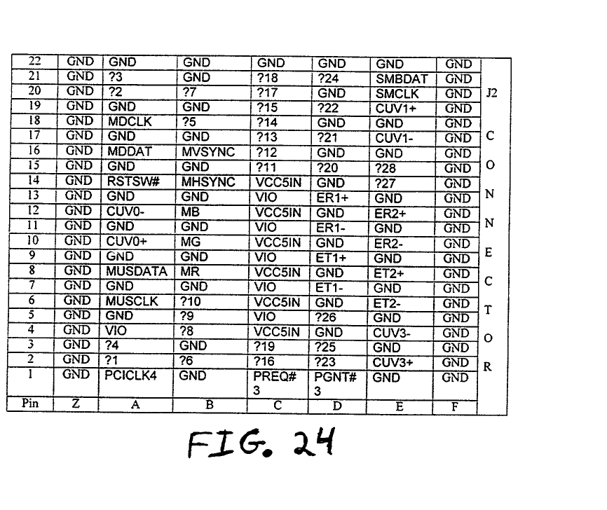

The user defined J2 pinout assignments for the CPUs of the processor cards 35 are shown in FIG. 24. In the table of FIG. 24 PCICLK4 represents the pci clock signal, MUSCLK/MUSDATA represents the mouse signal, CUVx represents the USB signal, MDDAT/MDCLK represents the keyboard signal, MR, MG, MB represents the VGA RGB signal, MHSYNC, MVSYNC represents the VGA synch signal, PREQ#3, PGNT#3 represents the pci req/gnt signal, ETx represents the Ethernet T sign, ERx represents the Ethernet R signal, SMCLK/SMBDAT represents the monitor signal and ?× means that the signal lead is not being used.

A fiber channel path can also be implemented through the CPCI J2 bus. The hard drive 71 can be a fiber channel hard drive, in which case the fiber channel bus 59 can communicate between the processor cards 35 and the hard drive 71. Also, connected to the J2 bus can be a fiber channel arbitrate hub or switch 69 for controlling the fiber channel. The fiber channel arbitrate hub or switch 69 can also serve as a network control card to implement a fiber network for communications between the processor cards 35.

The network control cards 63 can be 12 port 100 base T manageable network switches. Eight ports can connect to the CPCI J2 for routing to the processor cards 35. Four ports or an optional 1 GB port mounted to switch's front panel can be used for uplink to a network port.

Power is supplied by redundant N+1 load sharing power supply cards 73 through the power supply paths 61 utilizing the CPCI J2 bus and also through paths utilizing the J1 bus running through and across the midplane 33. The processor cards 35, for example, are supplied through the J1 bus while the expansion cards 35 are supplied through the J2 bus. The redundant power supply cards 73 can have 200-500W output capacity to provide +/−3.3V, +/−5V and 12V to the various card pinouts.

The KMV switch card 65 can use a standard CPCI 3U PCB. The KMV switch can switch any one of the processor cards' signals to a dedicated connector so that only one set of external keyboard, mouse and video monitor is needed to control all of the processor cards. The KMV switch can connect to the mouse using a USB mouse port 85 and can connect to the keyboard using a USB keyboard port 83.

The processor cards 35 and power supply cards 37 are mounted to the back side of the midplane board (see FIG. 5) while the multiple hard drive cards, the KMV switch card 65 and expansion cards 47 are mounted to the front side of the midplane board.

Each processor card controls two expansion cards 47 by sending CPI signals through the CPCI J1 bus passing through the midplane board providing increased throughput over the traditional CPCI arrangement (see FIG. 1) in which one controller card controls seven expansion cards. The CPCI expansion cards 47 can be any third party CPCI cards. The expansion cards 47 can, for example, be standard CPCI 3U expansion cards. The CPCI J1 connector is also used to supply power to the expansion cards 47 rather than supplying power through the J2 bus. In some embodiments the expansion cards can also be connected to the processor cards 47 and other cards through the CPCI J2 bus.

Mounting the processor cards 35 on the backside of midplane board 33 permits many of the benefits of the server array of the present invention. It allows for the high density placement of multiple processor cards 35 on a single midplane board 33. Also, mounting the processor cards 35 on the back side of the midplane 33 frees up more room for additional expansion cards 47 on the front side of the midplane board 33. Thus a network between the processor cards 35 and the expansion cards 47 controlled by the processor cards 35 can be formed on a single midplane board 33. Crucial to the placement of the processor cards 35 on the back side of the midplane board 33 is the implementation of a processor card J1 pinout which is the mirror image of the J1 pinout of traditional CPCI processor cards mounted on the front side of a backplane such as the backplane 11 of FIG. 1. The processor card 35 pinout follows that illustrated in FIG. 4. The J1 pinout for a traditional CPCI processor card mounted on the front side of a backplane follows that illustrated in FIG. 8. As can be seen from the figures, the J1 pinout assignments are the mirror images of each other.

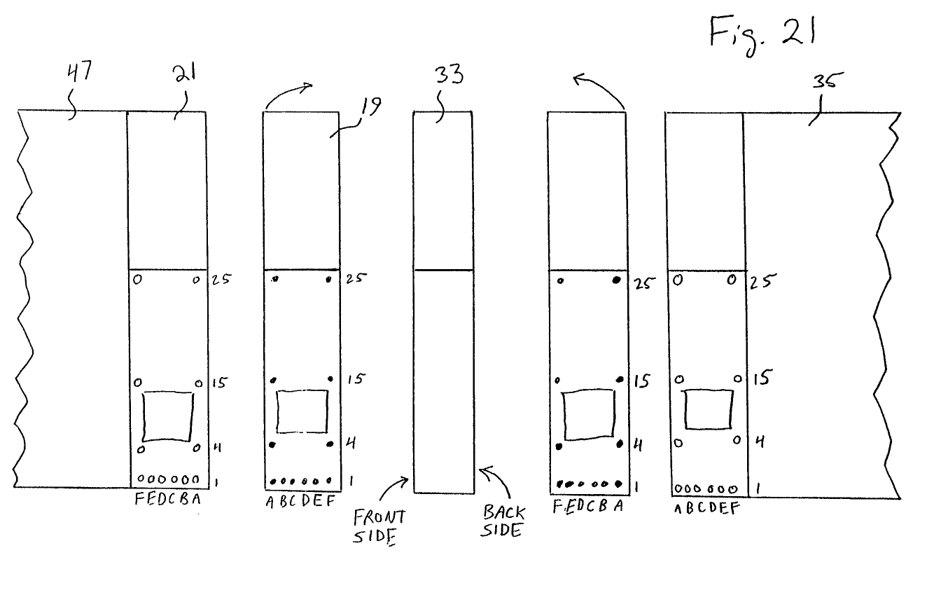

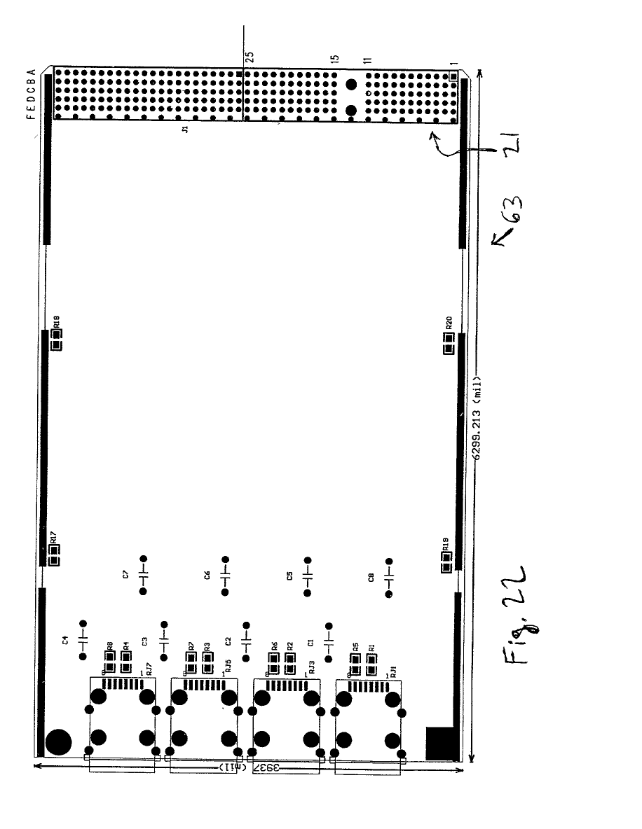

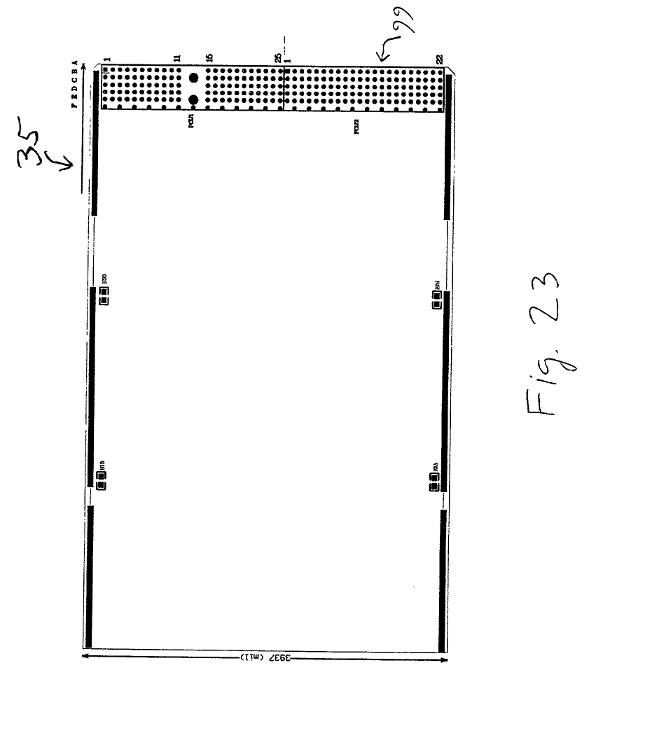

FIG. 21 shows the relationships between the pinouts of FIGS. 4 and 8. The pinout for an expansion card 21 or front-side mounted processor card reads F-A from left to right. The pinout of the back-side mounted processor card of the present invention reads A-F from left to right. In order to implement this design a new processor card 35 layout was invented rearranging the paths used in standard CPCI processor cards. Standard CPCI processor card “A” paths are routed to carry “F” I/O, “B” paths are routed to carry “E” I/O, “C” paths are routed to carry “D” I/O, “D” paths are routed to carry “C” I/O, and “E” paths are routed to carry “B” I/O, “F” paths are routed to carry “A” I/O. FIG. 22 shows a schematic diagram illustrating a network control card 63 with the female (socket) connector 21. FIG. 23 shows a schematic diagram illustrating a processor card 35 having a back-side female connector 99 which is the mirror image of the female connector 21 of FIG. 2.

The processor cards 35 utilize a modified CPCI card form factor by having longer lengths (between 240 millimeters and 320 millimeters) allowing for placement of more components and cheaper components on the cards while reducing overheating problems. In one particular embodiment, the cards have lengths of approximately 267 millimeters. The processor cards 35 utilize popular desktop PC or stand-alone server chipsets and have a modified modular CPCI form factor. Each processor card 35 has an on/off switch on its front panel. Each of the processor cards 35 can also connect directly to other peripherals, such as the hard drives 75 USB floppy drive, USB CD ROM drive, or other USB device, without going through the midplane 33, through use of an IDE bus 77, SCSI bus 79, or one or more USB port 81. Network active LED, power LED, and CPU normal LED indicators are located on the processor front panels of the processor cards 35. There are two kinds of processor card designs. A 3U processor card module has a 3U (5.25″) width and a 6U (10.5″) length. The 3U processor form factor can utilize 2 CPU's. A 6U processor card module has a 6U (10.5″) width and a 6U (10.5″) length. The 6U processor card form factor can, for example, utilize 4 CPU's with a built-in RAID SCSI or RAID EIDE controller.

The processor cards 35, hard drive cards 71 and network control cards 63 are redundant so that the high density server 31 continues to operate even if one or more of the cards fail thereby allowing for high availability and failover. Additionally, the high density server 31 utilizes the hot swap capability of CPCI to allow replacement of the cards while the high density server continues to operate, also resulting in high availability. A system monitoring module 67 (FIG. 9) can detect through the J2 bus when one of the other cards fail. It can then send an alert to notify of the failure. The alert can be passed through the network to the network switches 63 and then through the outside network to an outside location. Repair personal can then be notified of the failure, for example by automatically being paged. The repair personal can then remove the failed card and replace it while the server array continues normal operations using the hot swap capability. The system monitoring module can be implemented by a chip located on the KMV switch card, for example.

The system is easily upgradeable and expandable by adding or replacing any of the cards plugged into the front side or back side of the midplane. When new processors are developed and released only the processor cards need be replaced to upgrade the system resulting in tremendous upgrade flexibility. The hot swapping capability in such an economical system is very unique. Replacing failed cards or upgrading requires no system down time.

As described above, each processor card controls two expansion cards through PCI signals routed through the J1 bus. The multiple sets of processor cards and two expansion cards are redundant allowing load balancing among the sets. Also, if any of the processor cards or expansion cards fails than one of the redundant processor card/expansion card sets can take over any given task to provide failover. The power supply cards, hard drive cards and network control cards are similarly redundant allowing for load balancing and failover.

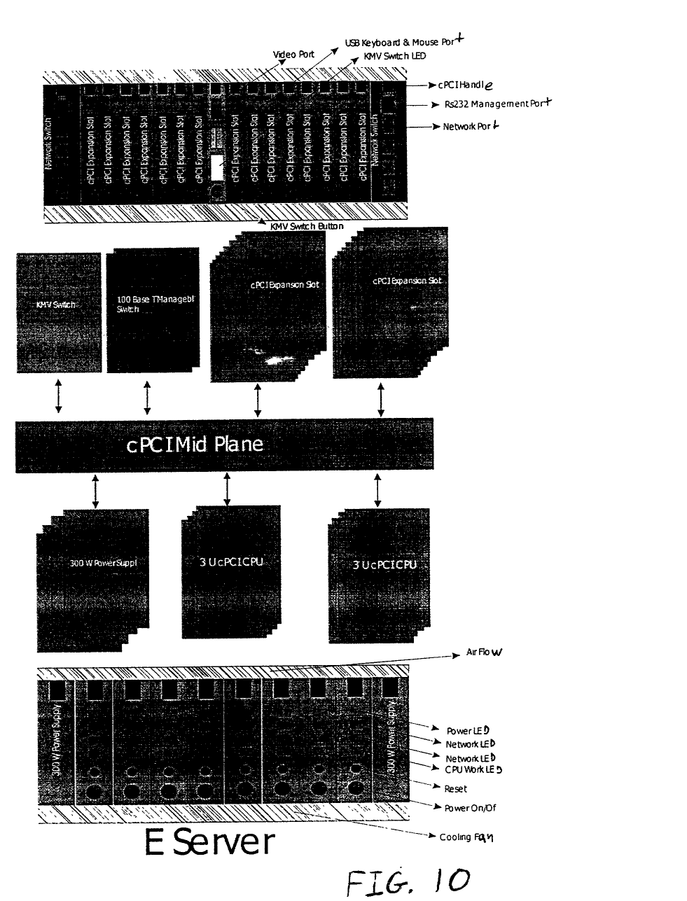

FIGS. 10-20 show various embodiments of the server array 31. FIG. 10 illustrates a server array for e-server applications. It includes 8 vertically oriented 3U width processor cards in a single row. Each processor card has a single CPU. The server is enclosed in a 19″, 4U box.

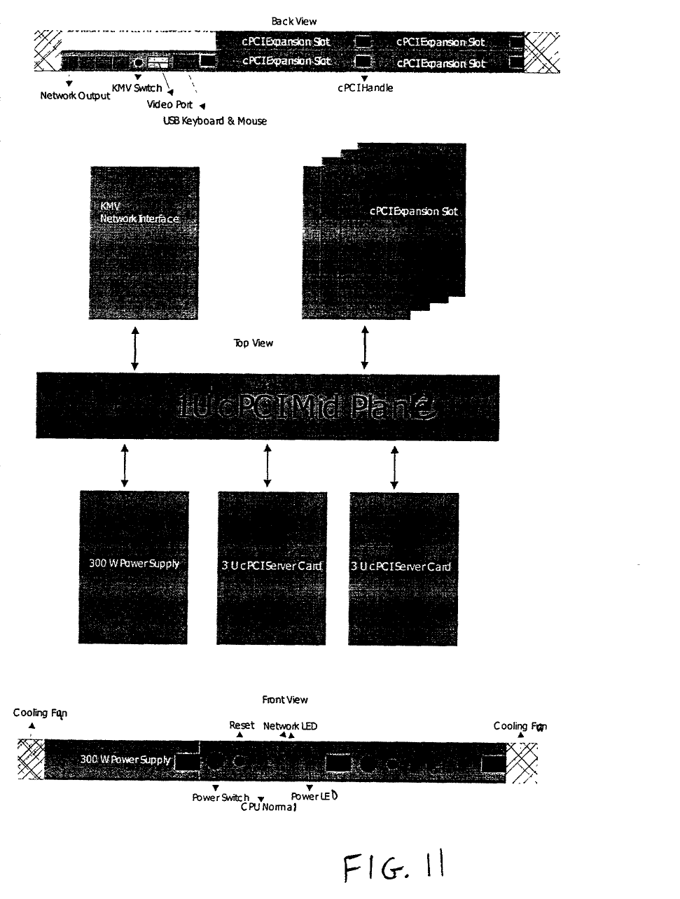

FIG. 11 illustrates a server array for terminal server, web server, network routing or security applications. It includes 2 horizontally oriented 3U width processor cards adjacent to each other. Each processor card has a single CPU. The server is enclosed in a 19″, 1U box.

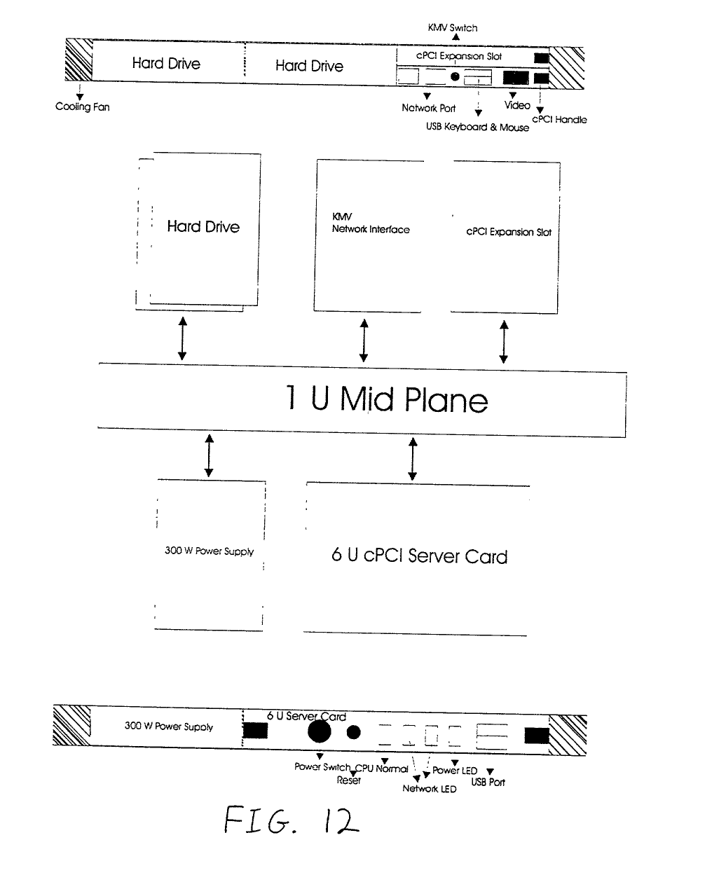

The server array of FIG. 12 includes 1 horizontally oriented 6U width processor card. The processor card has a single CPU. The server is enclosed in a 19″, 4U box and includes two hard drives.

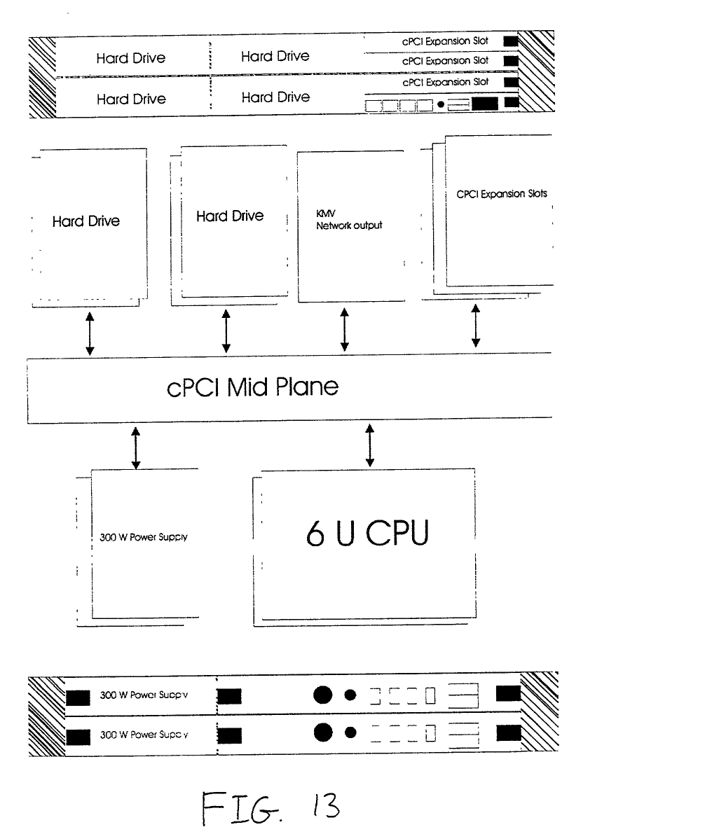

FIG. 13 illustrates a server array to serve as a small business server. It includes 2 horizontally oriented 6U width processor cards stacked in a single column. Each processor card has a single CPU. The server is enclosed in a 19″, 2U box and includes four hard drives.

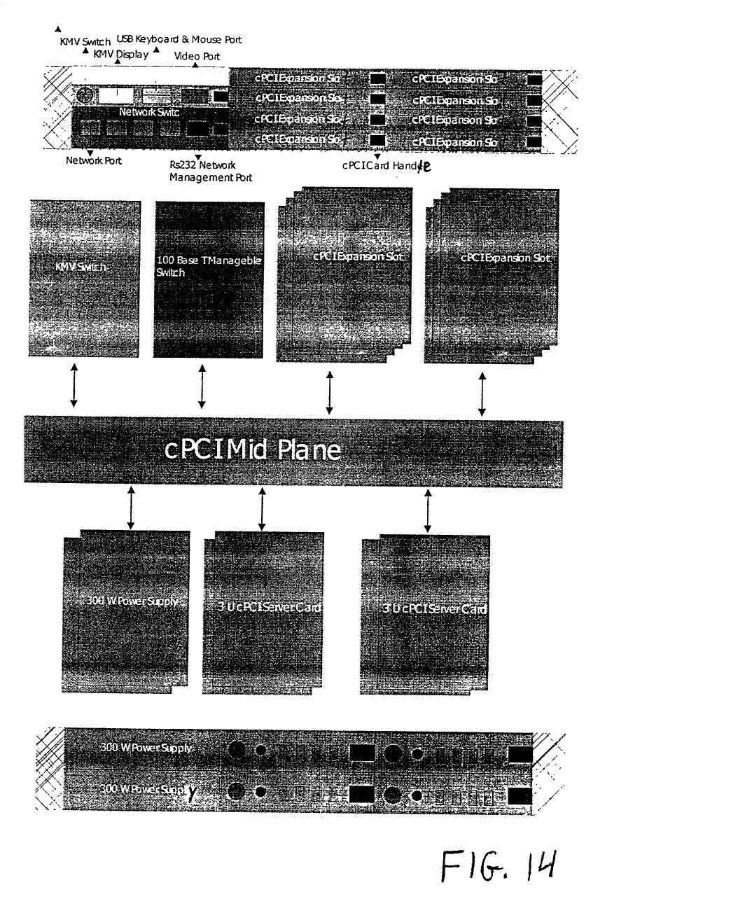

FIG. 14 illustrates a server array for utility server applications. It includes 4 horizontally oriented 3U width processor cards stacked in two columns of two cards each. Two processor cards have a single CPU and two processor cards have dual CPUs. The server is enclosed in a 19″, 2U box.

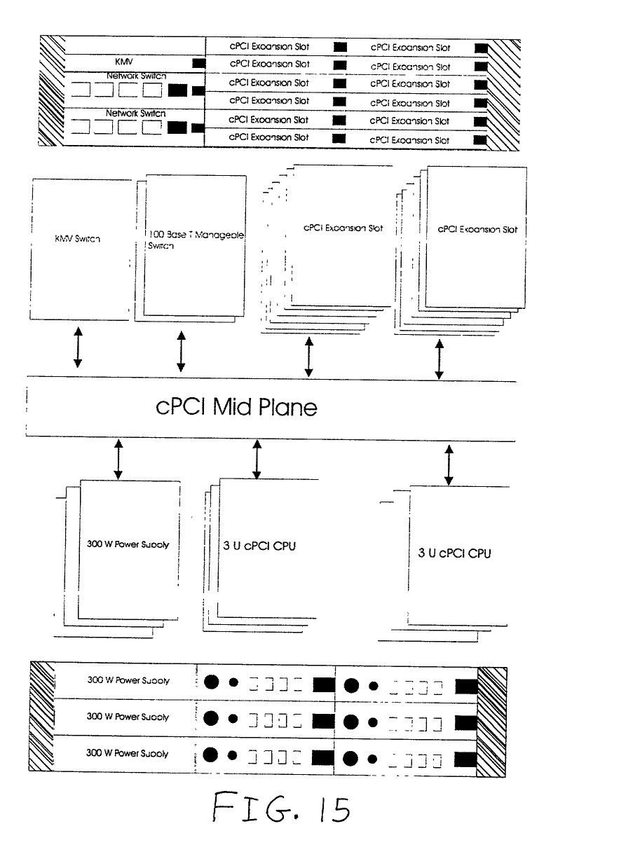

FIG. 15 illustrates a server array also for utility server applications. It includes 6 horizontally oriented 3U width processor cards stacked in two columns of three cards each. Each processor card has a single CPU. The server is enclosed in a 19″, 3U box.

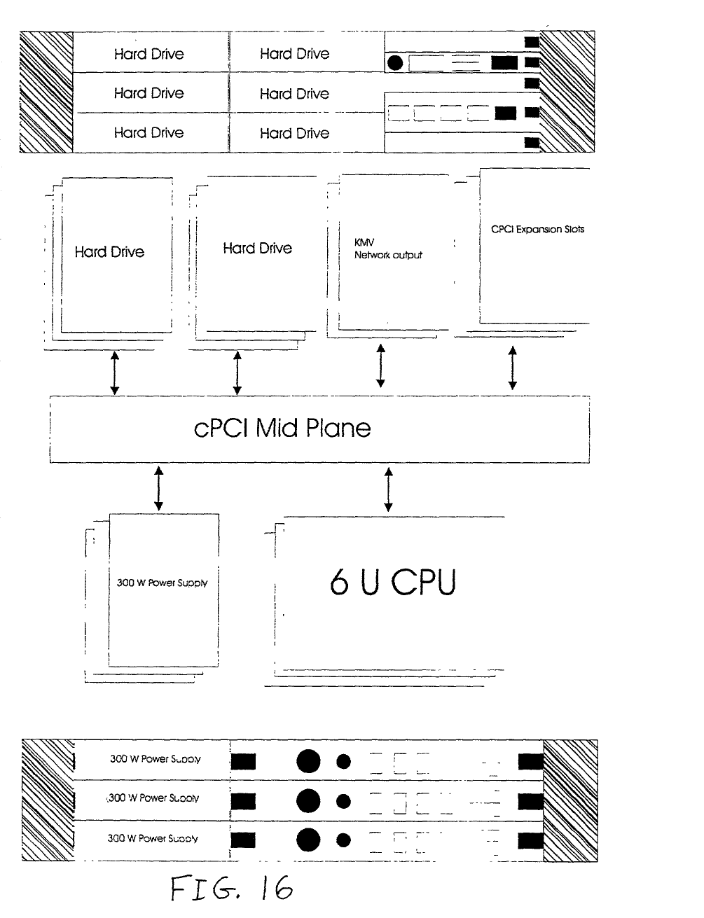

FIG. 16 illustrates a server array used for enterprise server applications. It includes 3 horizontally oriented 6U width processor cards stacked in a single column. Each processor card has two CPUs. The server is enclosed in a 19″, 3U box and includes 3 hard drives and two KMV switches.

FIG. 17 illustrates another utility server. It includes 8 horizontally oriented 3U width processor cards stacked in two columns of four cards each. Each processor card has a single CPU. The server is enclosed in a 19″, 4U box.

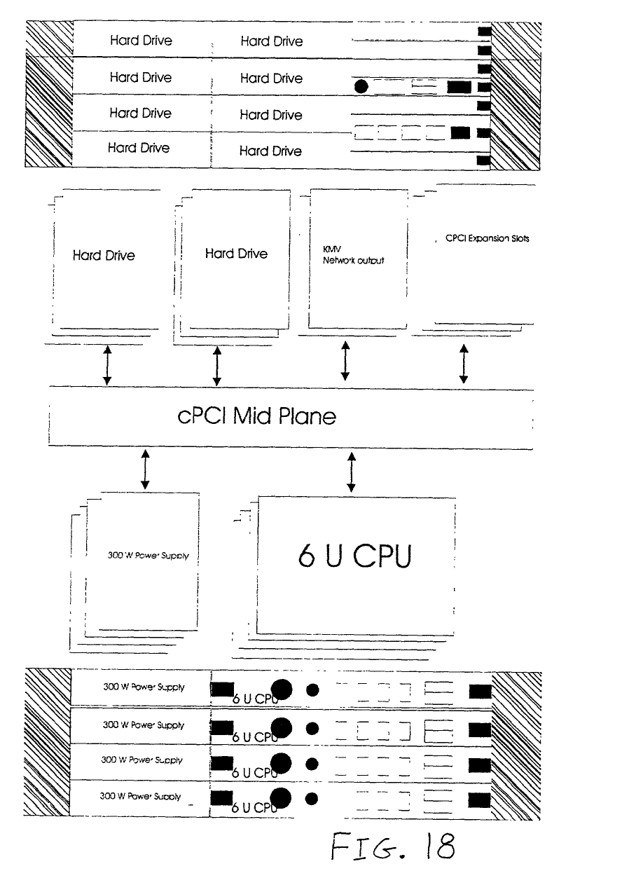

FIG. 18 illustrates a server array serving as an enterprise server. It includes 4 horizontally oriented 6U width processor cards stacked in a single column. Each processor card has a dual CPU. The server is enclosed in a 19″, 4U box and includes 8 hard drives.

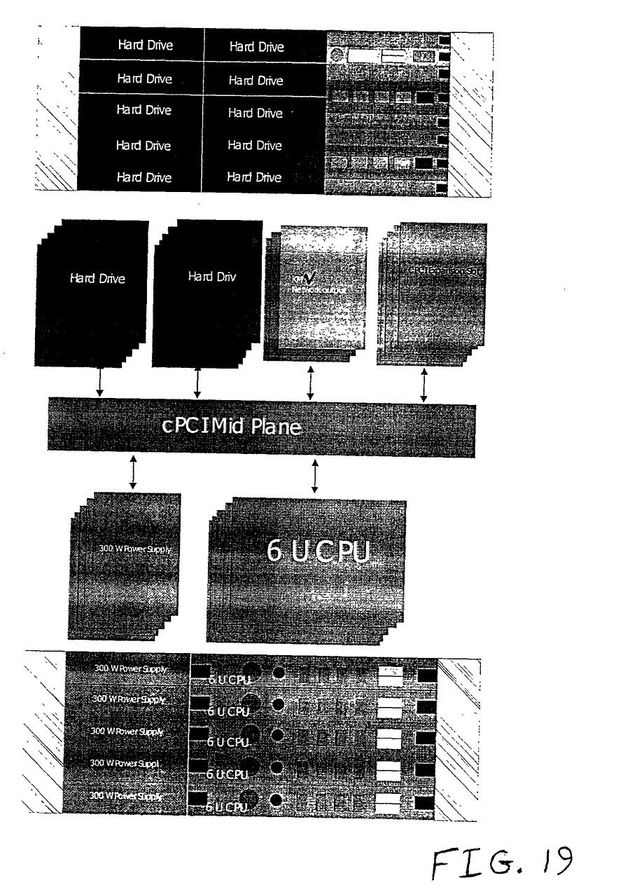

FIG. 19 illustrates a server array serving as a power server. It includes 5 horizontally oriented 6U width processor cards stacked in a single column. The 5 processor cards have a total of 8 CPUs. The server is enclosed in a 19″, 5U box and includes 10 hard drives and 3 KMV switches.

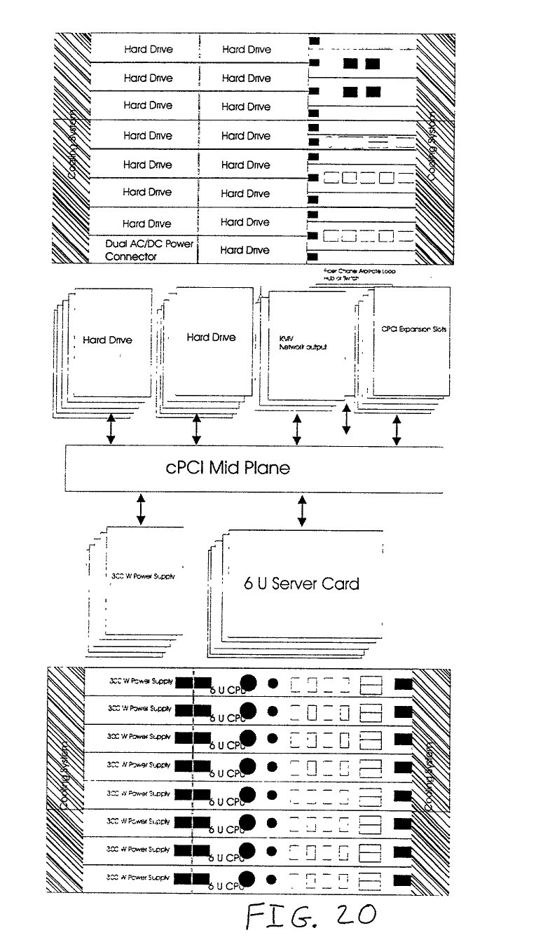

FIG. 20 illustrates another layout of a server array. It includes 8 horizontally oriented 6U width processor cards stacked in a single column. Each processor card has a single CPU. The server is enclosed in a 19″, 8U box which includes 15 hard drives and two fiber channel arbitrate loop hubs or switches.

The high density server array of the present invention has many applications including: Corporate Server Farms, ASP/ISP facilities, mobile phone base station, video on demand, and Web Hosting Operations.

It is to be understood that other embodiments may be utilized and structural and functional changes may be made without departing from the scope of the present invention. The foregoing descriptions of embodiments of the invention have been presented for the purposes of illustration and description. It is not intended to be exhaustive or to limit the invention to the precise forms disclosed. Accordingly, many modifications and variations are possible in light of the above teachings. It is therefore intended that the scope of the invention be limited not by this detailed description.

I claim:

1. A high density server comprising:
a midplane board;
multiple hot swappable processor cards having lengths of between 240 millimeters and 318 millimeters and multiple hot swappable power supply cards horizontally mounted on a back side of the midplane board;
multiple hot swappable hard drive cards, multiple hot swappable network control cards, multiple expansion cards and a KMV switch card horizontally mounted to a front side of the midplane board;
a CPCI J2 bus formed on the midplane board connecting the processor cards, the hard drive cards and the KMV switch, forming a network controlled by the multiple network control cards, wherein the multiple power supply cards supply power to the processor cards and hard drive cards through the CPCI J2 bus; and
CPCI J1 female connectors on each of the server cards having pinouts the mirror images of the pinouts of the CPCI J1 female connectors on each of the expansion cards;
and wherein each of the server cards controls at least two of the expansion cards using PCI signals routed though a CPCI J1 bus passing through the midplane board.

2. The high-density server of claim 1 wherein each of the processor cards controls exactly two of the expansion cards.

3. The high-density server of claim 1 comprising exactly 8 processor cards mounted on the midplane board.

4. A high-density server comprising:
a midplane board having opposing front and back sides;
a midplane board front-side connector connected to the front side of the midplane board;
an expansion card having an expansion-card connector connected to the front-side connector;
a midplane board back-side connector connected to the back side of the midplane board;
electrically conductive leads passing through the midplane board and electrically connecting the expansion card to the back-side connector; and
a processor card having a processor-card connector connected to the back-side connector such that the pinout assignments of the processor card are the mirror images of the pinout assignments of the expansion card.

5. The server of claim 4, wherein:
the midplane board front-side connector is one of multiple midplane board front-side connectors connected to the front side of the midplane board;
the expansion card is one of multiple expansion cards each having an expansion-card connector connected to the multiple midplane board front-side connectors;
the midplane board back-side connector is one of multiple midplane board back-side connectors connected to the back side of the midplane board;
additional electrically conductive leads pass through the midplane board electrically connecting at least two of the multiple expansion cards to at least one of the multiple midplane board back-side connectors; and
the processor card is one of multiple processor cards each having a processor-card connector connected to the midplane board back-side connectors such that the pinout assignments of the additional processor cards are the mirror images of the pinout assignments of the expansion cards and so that at least one of the processor cards can control at least two of the expansion cards.

6. The server of claim 5, further comprising:
conductive traces extending along the midplane board electrically connecting the processor cards; and
a network control card connected to the conductive traces and controlling a network formed between the processor cards and conductive traces.

7. The server of claim 6, wherein the network further comprises a KMV switch for switching electrical communications between a keyboard, mouse and video switch and the multiple processor cards.

8. The server of claim 6, wherein the network control card is one of the set consisting of a network switch, a network hub, a fiber channel arbitrate loop hub and a fiber channel arbitrate loop switch.

9. The server of claim 6, wherein the conductive traces connect the processor cards to the network control card in a daisy-chain or star network configuration.

10. The server of claim 6, further comprising additional redundant network control cards electrically connected to the processor cards via the traces for controlling the network.

11. The server of claim 6, wherein the network further comprises a fiber channel hard drive connected to the front side of the midplane board.

12. The server of claim 6, further comprising multiple power supply cards attached to the midplane for supplying power to the processor cards via the traces.

13. The server of claim 4, wherein:
the midplane board front-side connector has a first half with 5 rows of 22 midplane board front-side connector pins;
the expansion-card connector has a first half with 5 rows of 22 sockets for receiving the midplane board front-side connector pins thus forming a front-side connection interface;
the midplane board back-side connector has a first half with 5 rows of 22 midplane board back-side connector pins
the processor-card connector has a first half with 5 rows of 22 sockets for receiving the midplane board back-side connector pins thus forming a back-side connection interface; and
wherein the back-side connection interface is the mirror image of the front-side connection interface.

14. The high-density server of claim 4, wherein the pinout assignments of the expansion card are standard J1 CompactPCI assignments and the processor card is configured to utilize the mirror image of standard J1 CompactPCI pinout assignments.

15. A high-density server comprising:
a midplane board having opposing front and back sides;
multiple processor cards physically and electrically connected to the midplane board;
multiple network control cards physically and electrically connected to the midplane board; and
multiple power supply cards physically and electrically connected to the midplane board.

16. The high-density server of claim 15, wherein the processor cards, network control cards and power supply cards are connected to the midplane board via CompactPCI connectors.

17. The high-density server of claim 16, wherein the processor cards have pinout definitions the mirror image of J1 CompactPCI front side pinout definitions.

18. The high-density server of claim 16, wherein pin connectors are attached to the midplane board and socket connectors are attached to the processor cards, network control cards and power supply cards and wherein pins of the pin connectors are secured into sockets of the socket connectors to physically and electrically connect the multiple processor cards, multiple network control cards and multiple power supply cards to the midplane.

19. The high-density server of claim 15, further comprising a KMV switch physically and electrically connected to the midplane board.

20. The high-density server of claim 15, further comprising multiple fiber channel hard drive cards physically and electrically connected to the midplane board.

21. The high-density server of claim 15, wherein the network control cards are selected from the group consisting of a network switch, a network hub, a fiber channel arbitrate loop hub and a fiber channel arbitrate loop switch.

22. The high-density server of claim 16, wherein at least one of the multiple processor cards controls at least two expansion cards through a J1 portion of a CompactPCI connector.

23. The high-density server of claim 16, further comprising conductive traces extending along the midplane board to electrically connect the multiple processor cards, multiple network control cards and multiple power supply cards through J2 portions of the CompactPCI connectors.

24. The high-density server of claim 23, wherein the multiple network control cards control through J2 portions of the CompactPCI connectors a network formed from the multiple processor cards, multiple network control cards, multiple power supply cards and connecting conductive traces.

25. The server of claim 24, wherein the conductive traces connect the multiple processor cards, multiple network control cards, and multiple power supply cards in a daisy-chain or star network configuration.

26. The server of claim 24, further including a chassis enclosing the midplane board, multiple processor cards, multiple network control cards, and multiple power supply cards.

27. The server of claim 24, wherein the processor cards, network control cards and power supply cards are hot swappable so that any of the cards can be replaced without shutting down the network.

28. The server of claim 24, wherein the network will continue to operate even if any one of the processor cards, network control cards and power supply cards fails to operate.

30. The server of claim 15 wherein:
the front and back sides of the midplane board are substantially rectangular with a longer edge of the rectangle defining an x-axis
each of the processor cards have a processor card front and back side having a shorter edge defining a y-axis;
and wherein the processor cards are physically connected to the midplane board in a vertical configuration so that the y-axis is substantially perpendicular to the x-axis.

31. The server of claim 15 wherein:
the front and back sides of the midplane board are substantially rectangular with a longer edge of the rectangle defining an x-axis
each of the processor cards have a processor card front and back side having a shorter edge defining a y-axis;
and wherein the processor cards are physically connected to the midplane board in a horizontal configuration so that the y-axis is substantially parallel to the x-axis.

32. A high-density server comprising:
a midplane board having opposing front and back sides;
multiple expansion cards physically and electrically connected to the front side of the midplane board through a CompactPCI pin connector;
multiple processor cards physically and electrically connected to the back side of the midplane board through a reversed CompactPCI pin connector;
wherein the processor cards have a length of greater than 160 millimeters.

33. The server of claim 32, wherein the processor cards have lengths of approximately 267 millimeters.

34. The server of claim 32, wherein the processor cards have widths of approximately 3U.

35. The server of claim 32, wherein the processor cards have widths of approximately 6U.

36. The server of claim 32, wherein the processor cards have lengths of between 240 millimeters and 320 millimeters.
